(19) United States
(12) Patent Application Publication
(10) Pub. No.: US 2004/0129996 A1
(43) Pub. Date: Jul. 8, 2004

(54) High-voltage output circuit for a driving circuit of a plasma

(76) Inventor: Hong Jae Shin, Seoul (KR)

Correspondence Address: NOTARO AND MICHALOS, 100 DUTCH HILL ROAD, SUITE 110, ORANGEBURG, NY, 10962-2100, US

(21) Appl. No.: 10/476,098

(22) PCT Filed: Apr. 30, 2002
(86) PCT No.: PCT/KR02/00796

(30) Foreign Application Priority Data
May 3, 2001 (KR) 2001/23948
May 4, 2001 (KR) 2001/24313

(51) Int. Cl. H01L 29/00

(52) U.S. Cl. 257/500

(57) ABSTRACT

A high-voltage output circuits according to the present invention comprise a high-voltage level shifter and a high-voltage output means including a high-voltage NMOS as a pull-up element, or a bootstrapping circuit, wherein the same input voltage as a predetermined output voltage and a data signal are inputted and an output voltage of a high-voltage pulse corresponding to the data signal is outputted, and which can prevent a drop in a threshold voltage of the high-voltage element with using high-voltage NMOS transistors only and therefore can reduce an area as compared with a structure using high-voltage PMOS transistors for a full swing.

### TECHNICAL FIELD

The present invention relates to a high-voltage output circuit for a driving circuit of a plasma display panel and the like. More particularly, the present invention relates to a high-voltage output circuit for a driving circuit of a plasma display panel which comprises a high-voltage level shifter and a high-voltage output means including a high-voltage NMOS as a pull-up element, wherein the same input voltage as a predetermined output voltage and a data signal are inputted and an output voltage of a high-voltage pulse corresponding to the data signal is outputted, and which can prevent a drop in a threshold voltage of the high-voltage element with using high-voltage NMOS transistors only and therefore can reduce an area as compared with a structure using high-voltage PMOS transistors for a full swing.

### BACKGROUND ART

FIG. 1 shows a control circuit block 100 in a conventional plasma display panel as a detailed block diagram. In FIG. 1, a clock signal, a data signal, and horizontal and vertical synchronizing signals are inputted to the control circuit block 100. A pulse of an aftermentioned waveform is applied to each address electrode 32 by means of a display data controller 105 and an address driver 101, and a pulse of an aftermentioned waveform is applied to each Y electrode 14 from an Y common driver 104 by means of a scan driver controller 107, a common driver controller 108 and an Y common driver 104 of a panel driving controller 106. Further, a pulse of an aftermentioned waveform by means of the common driver controller 108 and an X common driver 103.

There are a selective write address method and a selective erase address method in the driving method of the plasma display panel. In the selective write address method, electric charges are formed only for display cells 36a to be turned on in an address discharge period after making electric charge in all discharge cells zero in a reset period. Then, sustain discharges are carried out. In the selective erase address method, uniform charges are formed for all display cells 36a in the reset period and then is erased only for display cells 36a to be turned off in an address discharge period. Subsequently, sustain discharges are carried out for the rest cells.

FIG. 2 illustrates a waveform for driving the conventional plasma display panel in a selective write address method. In FIG. 2, all Y electrodes become a level of 0 V during a reset period of each subfield, and at the same time a full writing pulse of a high-voltage(about 350 V) is applied to each X electrode. Then, discharge is executed for all display cells of all display lines despite of display states up to that time. At this time, an electric potential of an address electrode is about 100 V. By this full write discharge, wall charges are accumulated on a front dielectric layer covering the X electrodes and the Y electrodes. That is, minus wall charges are accumulated on the X electrodes and plus wall charges on the Y electrodes. Then, by making the potential of the X electrodes and the address electrodes 0 V, the voltage of wall charges themselves at all display cells becomes over a discharge starting voltage, thereby causing a discharge, which becomes self-neutralized and finished. That is called a self-erase discharge. By this self-erase discharge, the states of all display cells in the panel become uniform without any wall charge, thereby becoming states in which the subsequent address(write) discharge can be stably executed. And, as shown in FIG. 2, selectively and slowly increasing priming erase pulses can be applied to the Y electrodes. All display cells are completely initialized by additionally discharging cells, in which wall charges are not completely extinguished, using these priming erase pulses.

Next, in the address period, address discharge is executed in order to turn on or off the display cells according to the display data. First, a predetermind voltage(about 50 V) is applied to each X electrode and scan pulses(about −150 V) are applied to the Y electrodes in order. At the same time, address pulses(about 50 V) are selectively applied to the address electrodes corresponding to display cells to be turned on among the address electrodes, that is display cells where sustain discharges are carried out, thereby causing discharge between each address electrode for the display cells to be turned on and each Y electrode and accumulating quantity of wall charges to enable subsequent sustain discharges. And, a predetermined voltage(about −50V) is applied to the Y electrodes to which scan pulses are not applied so as not to cause any sustain discharge.

Then, in the sustain discharge period, a sustain discharge pulse is alternatively applied to each Y electrode and each X electrode and the sustain discharge is performed, thereby displaying a picture of one subfield. That is, discharges occur in the display cells which wall charges are accumulated on during the address discharge period, when sustain discharge pulses are overlapped to the wall charges, while a discharge does not occur in the display cells which wall charges are not accumulated on during the address discharge period, although sustain discharge pulses are applied. Thus, a picture of one subfield can become displayed. And, in order to avoid a discharge between the address electrodes and the X electrodes or Y electrodes, a predetermined voltage(about 65V) is applied to the address electrodes.

FIG. 3 illustrates a circuit diagram of a high-voltage output terminal circuit of a conventional integrated circuit for driving the plasma display panel. In FIG. 3, the high-voltage output terminal circuit comprises a high-voltage level shifter to convert a logic voltage of the circuit into a high-voltage level of a desirable driving voltage, and a high-voltage output means to receive the voltage of the high-voltage level shifter as an input and to output it after buffering.

The high-voltage level shifter comprises a LVPMOS1 and a LVPMOS2 of low voltage PMOS transistors to function as a latch, a LVNMOS1 and a LVNMOS2 of low voltage NMOS transistors as an input part which a low level voltage is applied to, and a HVPMOS1 and a HVPMOS2 of high voltage PMOS transistors to protect the LVNMOS1 and the LVNMOS2 as the input part. The high-voltage output means comprises a HVPMOS3 of a high voltage PMOS transistor, and a HVNMOS1, a HVNMOS2 and a HVNMOS3 of high voltage NMOS transistors.

When a data signal of 0V as a low signal is applied, the LVNMOS1 becomes turned off, and the LVNMOS2 on since a high signal of 5V is applied after passing through an inverter. Then, a voltage V_{H} is applied to a node 1 and a voltage (V_{H}−V_{Z}) is applied to a node 2, wherein V_{Z} is a voltage of a Zener diode which is commonly 5V. As a result, the HVPMOS3 becomes turned on and a voltage V_{H} is applied to a node 3. At this time, 0V of a low signal is applied to the HVNMOS1 and the HVNMOS3 of the high-voltage output means, which are kept in an OFF state, and a voltage V_{H} is applied to a gate part of the HVNMOS2. Thus, a voltage (V_{H}−V_{THN}) dropped by a threshold voltage V_{THN} of a high-voltage NMOS transistor from an input voltage V_{H} of a high-voltage is outputted as a final output voltage HVₒᵤₜ For example, when V_{H} is 180V and the threshold voltage V_{THN} of a high-voltage NMOS transistor is 2V, 178V becomes outputted. When the data signal becomes 5V of a high signal, 0V becomes outputted contrary to the above. That is, a PMOS is around two times bigger in size than an NMOS in size of a device for providing hundreds of milliampere in current where a high-voltage PMOS device is adopted as a pull-up device of a high-voltage output terminal so that an input voltage V_{H} of a high-voltage to an IC chip becomes an output voltage HVₒᵤₜ. Therefore, there is one problem that size of the IC chip becomes bigger than in case of an employment of a high-voltage NMOS as the pull-up device. Also, where a high-voltage NMOS is employed as the pull-up device in order to reduce size, it is disadvantageous that a voltage (V_{H}−V_{THN}) dropped by a threshold voltage V_{THN} of a high-voltage NMOS transistor from an input voltage V_{H} of a high-voltage is outputted as an output voltage HVₒᵤₜ.

### DISCLOSURE OF INVENTION

Accordingly, the present invention is made in order to solve the above problems, and one object of the present invention is to provide a high-voltage output circuit for a driving circuit of a plasma display panel which comprises a high-voltage level shifter and a high-voltage output means including a high-voltage NMOS as a pull-up element, wherein the same input voltage as a predetermined output voltage and a data signal are inputted and an output voltage of a high-voltage pulse corresponding to the data signal is outputted, and which can prevent a drop in a threshold voltage of the high-voltage element with using high-voltage NMOS transistors only and therefore can reduce an area as compared with a structure using high-voltage PMOS transistors for a full swing.

To accomplish the object of this invention, a high-voltage output circuit for a driving circuit of a plasma display panel is provided in accordance with one embodiment of the invention, which comprises a high-voltage level shifter and a high-voltage output means including a high-voltage NMOS as a pull-up element, wherein the same input voltage as a predetermined output voltage and a data signal are inputted and an output voltage of a high-voltage pulse corresponding to the data signal is outputted, said high-voltage output circuit being characterized by further comprising: a boosting voltage generator between the input voltage and the high-voltage level shifter for raising the input voltage to a higher voltage by a threshold voltage of a high-voltage NMOS transistor so as to prevent a voltage drop in the output voltage of the high-voltage NMOS of the high-voltage output means.

Said high-voltage level shifter comprising: a LVPMOS1 and a LVPMOS2 transistors for constituting a latch; a HVPMOS1 and a HVPMOS2 transistors for clamping a gate voltage of, and protecting, the LVPMOS1 and the LVPMOS2 transistors; a LVNMOS1 and a LVNMOS2 transistors for turning on/off the LVPMOS1 transistor and turning off/on the LVPMOS2 transistor by means of the HVPMOS1 and the HVPMOS2 transistors by becoming off and on/on and off by means of a low signal/a high signal of the data line, respectively; a HVNMOS1 and a HVPMOS3 transistors to become off/on and on/off by means of the low signal/the high signal of the data line, respectively, so as to apply a voltage to a gate of the high-voltage NMOS transistor of the high-voltage output means from said HVPMOS3 transistor when the data line is a low signal.

Furthermore, the present invention is to provide a high-voltage output circuit for a driving circuit of a plasma display panel, in accordance with another embodiment of the invention, which comprises a high-voltage level shifter and a high-voltage output means including a high-voltage NMOS transistor as a pull-up element, wherein the same input voltage as a predetermined output voltage and a data signal are inputted and an output voltage of a high-voltage pulse corresponding to the data signal is outputted, said high-voltage output circuit being characterized by further comprising: a bootstrapping high-voltage level shifter between the high-voltage level shifter and the high-voltage output means for raising the input voltage to a higher voltage by a threshold voltage of a high-voltage NMOS transistor so as to prevent a voltage drop in the output voltage of the high-voltage NMOS of the high-voltage output means. The bootstrapping high-voltage level shifter shown in FIG. 7 comprises a charge pumping means having a buffer and a capacitor for the bootstrapping, thereby applying a higher voltage by the threshold voltage than the final output voltage to a gate part of the high-voltage NMOS transistor or the pull-up element of the high-voltage output means and being capable of outputting the input voltage without dropping the threshold voltage on outputting the high-voltage. The high-voltage level shifter comprises a LVP1 and a LVP2 transistors for constituting a latch; a HVP1 and a HVP2 transistors for clamping a gate voltage of, and protecting, the LVP1 and the LVP2 transistors; a LVN1 and a LVN2 transistors for turning on/off the LVP1 transistor and turning off/on the LVP2 transistor by means of the HVP1 and the HVP2 transistors by becoming off and on/on and off by means of a low signal/a high signal of the data line, respectively; a HVN1 and a HVP3 transistors to become off/on and on/off by means of the low signal/the high signal of the data line, respectively, so as to apply a voltage to a gate of the high-voltage NMOS transistor of the high-voltage output means 120 from said HVP3 transistor when the data line is a low signal.

The high-voltage output circuits of such constructions can be included by a scan driving IC and a data driving IC as a driving IC of a plasma display panel and by a scan driving IC and a data driving IC as a driving IC of a flat display.

### BRIEF DESCRIPTION OF THE DRAWINGS

FIG. 1 is a detailed block diagram showing a control circuit and a driving part in a conventional plasma display panel.

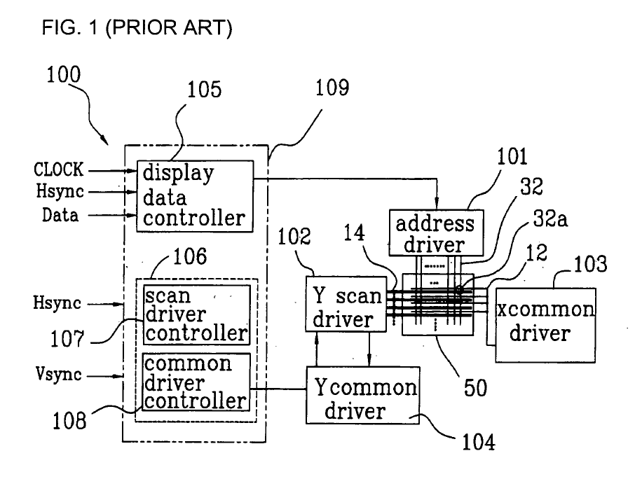

FIG. 2 is a waveform for driving the conventional plasma display panel in a selective write address method.

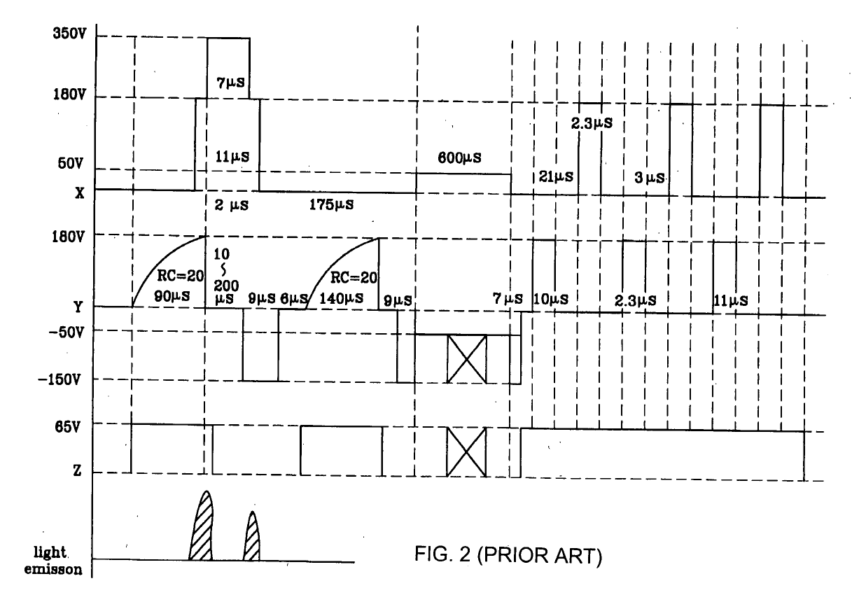

FIG. 3 illustrates a circuit diagram of a high-voltage output terminal circuit of a conventional integrated circuit for driving the plasma display panel.

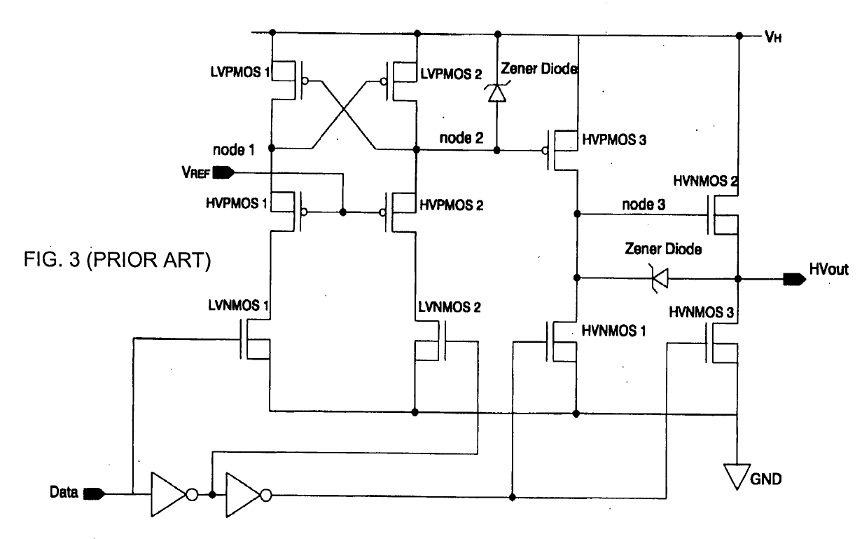

FIG. 4 is a block diagram of a high-voltage output terminal circuit of an integrated circuit for driving the plasma display panel according to one embodiment of the present invention.

FIG. 5 is a detailed circuit diagram of FIG. 4.

FIG. 6 is a block diagram of a high-voltage output terminal circuit of an integrated circuit for driving the plasma display panel according to another embodiment of the present invention.

FIG. 7 is a detailed circuit diagram of FIG. 6.

FIGS. 8a to 8c illustrate waveforms at nodes 2 and 3 for comparing an output voltage in the conventional high-voltage output terminal circuit with an output voltage in the high-voltage output terminal circuit according to the present invention.

### BEST MODE FOR CARRYING OUT THE INVENTION

Now, a preferred embodiment of the present invention will be described in detail with reference to the accompanying drawings.

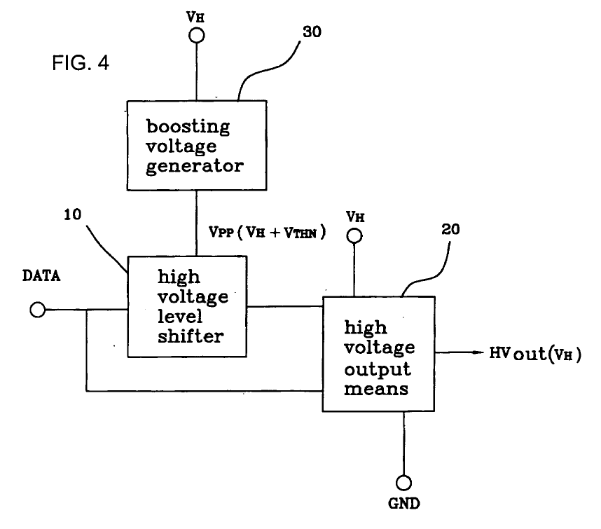

a high-voltage output terminal circuit of an integrated circuit for driving the plasma display panel according to one embodiment of the present invention is illustrated as an block diagram in FIG. 4.

In FIG. 4, the high-voltage output terminal circuit of an integrated circuit for driving the plasma display panel and the like according to one embodiment of the present invention, as described with reference to the prior art, which can be employed as an output terminal of a driving IC to be used in a circuit for driving the plasma display panel, performs a function of converting an interior logic voltage level of the driving IC into a high-voltage level.

The high-voltage output terminal circuit comprises a high-voltage level shifter 10 for converting a logic voltage of the circuit into a high-voltage level of a desirable driving voltage V_{H} for a plasma display panel, and a high-voltage output means 20 for receiving the voltage of the high-voltage level shifter 10 as an input and outputting a high-voltage, the high-voltage output means 20 performing a push-pull action. That is, where high-voltage PMOS devices are used as a pull-up device of a high-voltage output terminal, an input high-voltage V_{H} to a chip becomes an output voltage HVₒᵤₜ. However, in size of a device capable of supplying hundreds of milliampere in current, a PMOS transistor is around two times the size of an NMOS transistor, and therefore in size of IC, one using high-voltage PMOS transistors becomes bigger than that using high-voltage NMOS transistors. Meanwhile, where high-voltage PMOS transistors are used as a pull-up device of a high-voltage output terminal, it is advantageous that the size can be reduced, but, disadvantageously, since an input voltage V_{H} of an high-voltage is dropped by a threshold voltage V_{THN} of an high-voltage NMOS transistor, the dropped voltage (V_{H}−V_{THN}) is outputted as an output voltage HVₒᵤₜ.

Therefore, in the present invention, a high-voltage output terminal circuit of a driving IC in a plasma display panel is provided which the same voltage V_{H} as the input high-voltage V_{H} can become the output voltage HVₒᵤₜ with using high-voltage NMOS transistors as the pull-up device of the high-voltage output terminal

That is, in FIG. 4, in order to prevent the drop of the output voltage HVₒᵤₜ, the present invention is characterized in that a boosting voltage generator 30 is provided between the input voltage V_{H} and the high-voltage level shifter 10, which can raise the input voltage V_{H} to a higher voltage (V_{H}+V_{THN}) by a threshold voltage V_{THN} of a high-voltage NMOS transistor and apply the higher voltage (V_{H}+V_{THN}) to the high-voltage level shifter 10. Any boosting voltage generator 30 can be adopted if it can raise a voltage by the threshold voltage V_{THN} however it may be constituted according to the prior art.

In FIG. 4, the present invention comprises the boosting voltage generator 30, the high-voltage level shifter 10 for converting a logic voltage into a high-voltage level of a desirable driving voltage for a plasma display panel, and an HVNMOS2 and an HVNMOS3 transistors as the high-voltage output means 20 for receiving the voltage of the high-voltage level shifter 10 as an input and outputting a high-voltage after buffering. The boosting voltage generator 30 receives a voltage V_{H} as an input voltage and generates a voltage V_{PP}(V_{H}+V_{THN}). Therefore, a switching voltage at the gate part of the HVNMOS2 has a range of 0V to a voltage (V_{H}+V_{THN}), said switching voltage being the output voltage of the high-voltage level shifter 10. As a result, the final output voltage HVₒᵤₜ performs a switching action of a voltage 0 to a voltage V_{H}, thereby performing a full swing action.

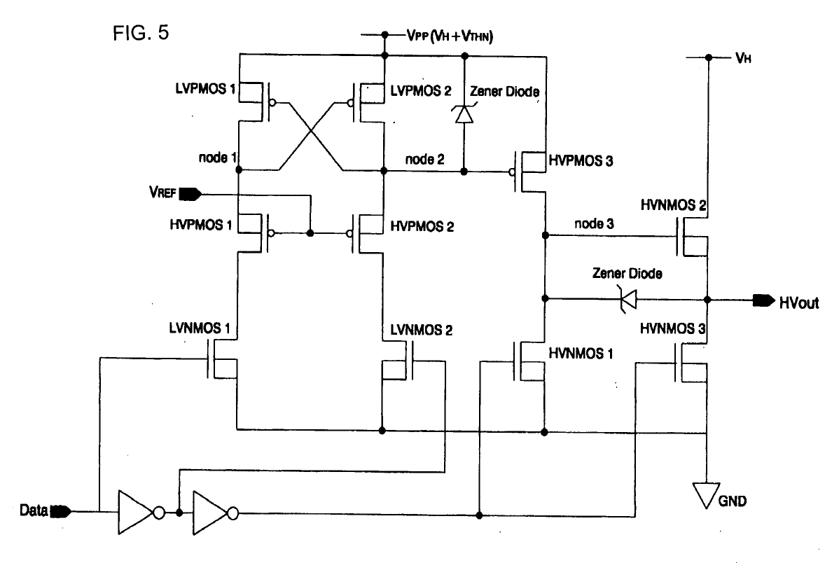

FIG. 5 illustrates a detailed circuit diagram of FIG. 4. The operation is briefly described as follows. In FIG. 5, the same voltage as an output voltage is applied to a terminal V_{H}, and the output voltage (V_{H}+V_{THN}) of the boosting voltage generator 30 is applied to a terminal V_{PP} of the high-voltage level shifter 10. A voltage (V_{PP}−V_{Z}) of a reference voltage generator is applied to a terminal V_{REF}. A LVPMOS1 and a LVPMOS2 are low-voltage PMOS devices, and an HVPMOS1, an HVPMOS2 and an HVPMOS3 are high-voltage PMOS devices. Also, a LVNMOS1 and a LVNMOS2 are low-voltage NMOS devices, and a HVNMOS2 and a NVNMOS3 of an output terminal are high-voltage NMOS devices. All diodes used in here are Zenor diodes. The Zenor diodes D1 and D2 are turned on when a voltage between a gate and a source of the LVPMOS1 or the LVPMOS2 used as a latch is dropped above 5V, thereby performing a function of protecting the devices. A function of the HVPMOS1 and the HVPMOS2 is to protect the LVPMOS1 and the LVPMOS2 by clamping each gate voltage of the LVPMOS1 and the LVPMOS2. When a low signal of a data line Data becomes 0V, the LVNMOS1 becomes an OFF state and the LVNMOS2 passing an inverter becomes an ON state. As a result, the LVPMOS1 of the latch becomes an ON state and the LVPMOS2 becomes an OFF state. Thus, a voltage of a node 2 becomes a voltage (V_{PP}−V_{Z}(5V)), the HVPMOS3 becomes an ON state, and a voltage of a node 3 will be a voltage V_{PP}. In this case, since the HVMOS1 and the HVNMOS3 become an OFF state, the HVNMOS2 is kept in an ON state, and the HVNMOS3 is kept in an OFF state, a high-voltage is outputted from the output voltage terminal HVₒᵤₜ. Since a voltage V_{PP}(V_{H}+V_{THN}) is applied to a gate of the HVNMOS2, an output level of the high-voltage in the output voltage terminal HVₒᵤₜ, becomes a voltage V_{H}, which is not dropped by a threshold voltage V_{THN} of the HVNMOS2, the voltage V_{H} becoming outputted.

Meanwhile, if a high signal is applied to the data line Data, it operates to the contrary and a voltage 0V becomes outputted in the output voltage terminal HVₒᵤₜ.

Therefore, in the present invention, an input voltage V_{H} of a high-voltage applied can be outputted in itself with using a high-voltage NMOS as a pull-up element of a high-voltage output terminal and without dropping a voltage by a threshold voltage of the high-voltage element.

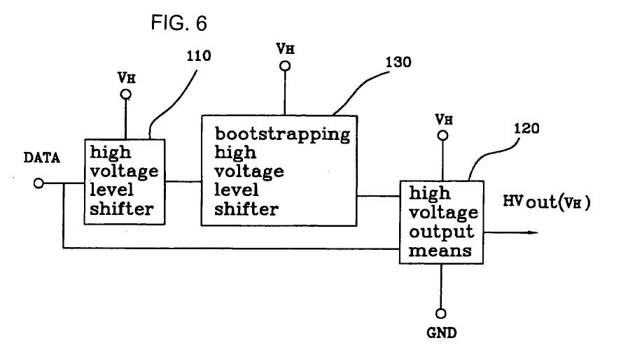

FIG. 6 illustrates a block diagram of a high-voltage output terminal circuit of an integrated circuit for driving the plasma display panel and the like according to another embodiment of the present invention. The high-voltage output terminal circuit, as one method of a bootstrapping level shifter, comprises a high-voltage level shifter 110 which is described in the above background art, a bootstrapping high-voltage level shifter 130 using an aftermentioned charge pumping means Cpump, and a high-voltage output means 120 including a HVN2 and a HVN3 of a high-voltage output terminal and for receiving the voltage of the high-voltage level shifter 10 as an input and outputting a high-voltage after buffering. In such a construction, a voltage is bootstrapped by a threshold voltage V_{THN} of the HVN2 in the bootstrapping high-voltage level shifter 130. A switching voltage at a gate part of the HVN2 as an output voltage of the bootstrapping high-voltage level shifter 130 has a range of 0V to a voltage (V_{H}+V_{THN}). As a result, the final output voltage HVₒᵤₜ performs a switching action of a voltage 0 to a voltage V_{H}, thereby performing a full swing action.

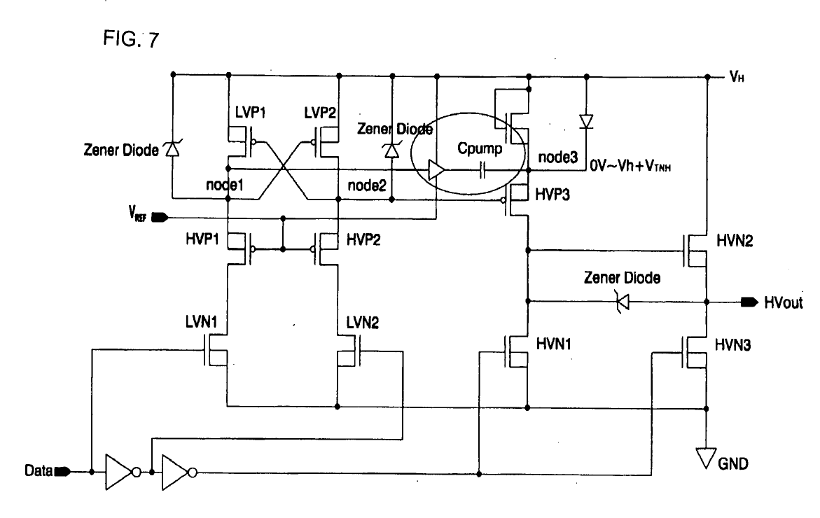

FIG. 7 illustrates a detailed circuit diagram of the high-voltage output terminal circuit for driving the plasma display panel. The operation is as follows. An output voltage is applied to a terminal V_{H}, and a voltage (V_{H}−V_{Z}) is applied to a terminal V_{REF} from a reference voltage generator. A LVP1 and a LVP2 are low-voltage PMOS devices, and an HVP1, an HVP2 and an HVP3 are high-voltage PMOS devices. Also, a LVN1 and a LVN2 are low-voltage NMOS devices, and a HVN2 and a NVN3 of an output terminal are high-voltage NMOS devices. All diodes used in here are Zenor diodes. The Zenor diodes D1 and D2 are turned on when a voltage between a gate and a source of the LVP1 or the LVP2 used as a latch is dropped above 5V, thereby performing a function of protecting the devices. A function of the HVP1 and the HVP2 is to protect the LVP1 and the LVP2 by clamping each gate voltage of the LVP1 and the LVP2. When a low signal of a data line Data becomes 0V, the LVN1 becomes an OFF state and the LVN2 passing an inverter becomes an ON state. As a result, the LVP1 of the latch becomes an ON state and the LVP2 becomes an OFF state. Thus, a voltage of a node 2 becomes a voltage (V_{H}−V_{Z}(5V)) and the HVPMOS3 becomes an ON state. In this time, a voltage of a node 3 will be kept in a voltage (V_{H}−V_{THN}) dropped by a threshold voltage V_{THN} of the HVN2, and a predetermined constant quantity of charges are supplied from the charge pumping means Cpump, being bootstrapped by a voltage ΔV_{B}. Therefore, a voltage in the node 3 becomes a voltage (V_{H}−V_{THN}+ΔV_{B}). Here, ΔV_{B} can be obtained from the equation of ΔV_{B}=V_{Z}·C_{B}/(C_{B}+C_{IN}).

Here, C_{B} is a capacitor of the charge pumping means Cpump, C_{IN} is an input capatance of a HVP3, and V_{Z} is a voltage between opposite terminals of the Zener diode. In an actual design, ΔV_{B} was set into a voltage of 2V_{THN}. In this case, the HVN1 and the HVN3 become an OFF state and the HVN2 is kept in an ON state, a high-voltage is outputted at the HVₒᵤₜ. Since a voltage (V_{H}+V_{THN}) is applied to a gate of the HVN2, a voltage V_{H}, which is not dropped by a threshold voltage V_{THN} of the HVN2, becomes outputted as an output level of the high-voltage in the output voltage terminal HVₒᵤₜ.

On the other hand, if a high signal is applied to the data line Data, it operates to the contrary and a voltage 0V becomes outputted in the output voltage terminal HVₒᵤₜ.

Thus, in this embodiment of the present invention, an input voltage V_{H} of a high-voltage applied can be also outputted as it is with using a high-voltage NMOS as a pull-up element of a high-voltage output terminal and without dropping a voltage by a threshold voltage of the high-voltage element. At the same time, it is advantageous that the high-voltage output terminal occupies a smaller area as compared with a structure using high-voltage PMOS transistors for a full swing.

The above-mentioned high-voltage output terminal circuits according to the embodiments of the present invention are used for a scan driving IC and a data driving IC as a driving IC of a plasma display panel, or for a driving IC and a data driving IC as a driving IC of another flat display.

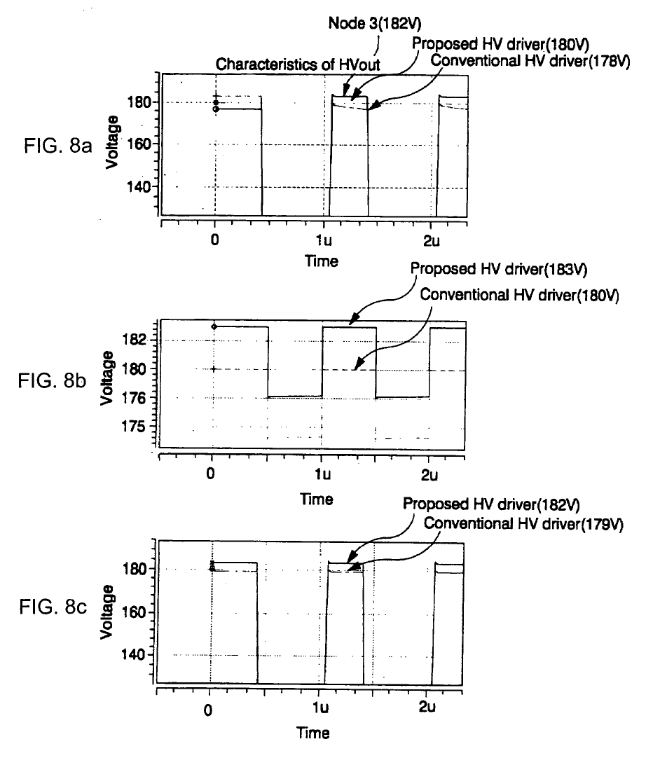

FIGS. 8a to 8c illustrate voltage waveforms at the output voltage terminal HVₒᵤₜ, and nodes 2 and 3 for comparing an output voltage in the conventional high-voltage output terminal circuit with an output voltage in the high-voltage output terminal circuit according to the present invention.

FIGS. 8a to 8c show results of an HSPICE simulation after applying 180V to V_{H} in the high-voltage output terminal circuit. FIG. 8a shows an output voltage HVₒᵤₜ of the conventional high-voltage output terminal circuit and of the high-voltage output terminal circuit according to the present invention as a proposed HV driver, which is showing that a full swing of 180V causes in the present invention, but a full swing does not occurs as the output voltage is 178V in the conventional circuit. Also, FIG. 8b shows a voltage at the node 2 of the high-voltage output terminal, and FIG. 8c shows a voltage at the node 3 of the high-voltage output terminal, wherein, at the node 2, the voltage in the high-voltage output terminal of the present invention shows 183V and the voltage in the conventional circuit shows 180V, while the voltage in the high-voltage output terminal of the present invention shows 182V at the node 3 and the voltage in the conventional circuit shows 179V at the node 3.

According to the configuration and acting of the high-voltage output circuits for a driving circuit of a plasma display panel and the like in accordance with the embodiments of the present invention described above, the high-voltage output circuits comprise a high-voltage level shifter and a high-voltage output means including a high-voltage NMOS as a pull-up element, or a bootstrapping circuit, wherein the same input voltage as a predetermined output voltage and a data signal are inputted and an output voltage of a high-voltage pulse corresponding to the data signal is outputted, and which can prevent a drop in a threshold voltage of the high-voltage element with using high-voltage NMOS transistors only and therefore can reduce an area as compared with a structure using high-voltage PMOS transistors for a full swing.

Although the invention has been described in connection with specific preferred embodiments, it should be understood that the present invention should not be unduly limited to such specific embodiments. It will be apparent for those skilled in the art that various modifications, improvements or applications are possible with respect to the shown embodiments within the scope of the present invention.

1. A high-voltage output circuit for a driving circuit of a plasma display panel and the like, which comprises a high-voltage level shifter 10 and a high-voltage output means 20 including a high-voltage NMOS as a pull-up element, wherein the same input voltage V_{H} as a predetermined output voltage HVₒᵤₜ and a data signal are inputted and an output voltage HVₒᵤₜ of a high-voltage pulse corresponding to the data signal is outputted, said high-voltage output circuit being characterized by further comprising:
a boosting voltage generator 30 between the input voltage V_{H} and the high-voltage level shifter 10 for raising the input voltage V_{H} to a higher voltage (V_{H}+V_{THN}) by a threshold voltage V_{THN} of a high-voltage NMOS transistor so as to prevent a voltage drop in the output voltage HVₒᵤₜ of the high-voltage NMOS of the high-voltage output means 20.

2. A high-voltage output circuit for a driving circuit of a plasma display panel and the like according to claim 1, said high-voltage level shifter 10 comprising:
a LVPMOS1 and a LVPMOS2 transistors for constituting a latch;
a HVPMOS1 and a HVPMOS2 transistors for clamping a gate voltage of, and protecting, the LVPMOS1 and the LVPMOS2 transistors;
a LVNMOS1 and a LVNMOS2 transistors for turning on/off the LVPMOS1 transistor and turning off/on the LVPMOS2 transistor by means of the HVPMOS1 and the HVPMOS2 transistors by becoming off and on/on and off by means of a low signal(0V)/a high signal of the data line, respectively;
a HVNMOS1 and a HVPMOS3 transistors to become off/on and on/off by means of the low signal(0V)/the high signal of the data line, respectively, so as to apply the higher voltage (V_{H}+V_{THN}) to a gate of the high-voltage NMOS transistor of the high-voltage output means 20 from said HVPMOS3 transistor when the data line is a low signal(0V).

3. A high-voltage output circuit for a driving circuit of a plasma display panel and the like according to claim 1 or claim 2, wherein said high-voltage output circuit is included by a scan driving IC and a data driving IC as a driving IC of a plasma display panel.

4. A high-voltage output circuit for a driving circuit of a plasma display panel and the like according to claim 1 or claim 2, wherein said high-voltage output circuit is included by a scan driving IC and a data driving IC as a driving IC of a flat display.

5. A high-voltage output circuit for a driving circuit of a plasma display panel and the like, which comprises a high-voltage level shifter 110 and a high-voltage output means 120 including a high-voltage NMOS transistor as a pull-up element, wherein the same input voltage V_{H} as a predetermined output voltage HVₒᵤₜ and a data signal are inputted and an output voltage HVₒᵤₜ of a high-voltage pulse corresponding to the data signal is outputted, said high-voltage output circuit being characterized by further comprising:
a bootstrapping high-voltage level shifter 130 between the high-voltage level shifter 110 and the high-voltage output means 120 for raising the input voltage V_{H} to a higher voltage (V_{H}+V_{THN}) by a threshold voltage V_{THN} of a high-voltage NMOS transistor so as to prevent a voltage drop in the output voltage HVₒᵤₜ of the high-voltage NMOS of the high-voltage output means 120.

6. A high-voltage output circuit for a driving circuit of a plasma display panel and the like according to claim 5, said bootstrapping high-voltage level shifter 130 comprising a charge pumping means Cₚᵤₘₚ having a buffer and a capacitor for the bootstrapping, thereby applying a higher voltage (V_{H}+V_{THN}) by the threshold voltage V_{THN} than the final output voltage HVₒᵤₜ to a gate part of the high-voltage NMOS transistor or the pull-up element of the high-voltage output means and outputting the input voltage V_{H} without dropping the threshold voltage V_{THN} on outputting the high-voltage.

7. A high-voltage output circuit for a driving circuit of a plasma display panel and the like according to claim 5 or claim 6, said high-voltage level shifter 110 comprising:
a LVP1 and a LVP2 transistors for constituting a latch;
a HVP1 and a HVP2 transistors for clamping a gate voltage of, and protecting, the LVP1 and the LVP2 transistors;
a LVN1 and a LVN2 transistors for turning on/off the LVP1 transistor and turning off/on the LVP2 transistor by means of the HVP1 and the HVP2 transistors by becoming off and on/on and off by means of a low signal(0V)/a high signal of the data line, respectively;
a HVN1 and a HVP3 transistors to become off/on and on/off by means of the low signal(0V)/the high signal of the data line, respectively, so as to apply a voltage (V_{H}+V_{THN}) to a gate of the high-voltage NMOS transistor of the high-voltage output means 120 from said HVP3 transistor when the data line is a low signal(0V).

8. A high-voltage output circuit for a driving circuit of a plasma display panel and the like according to claim 5 or claim 6, wherein said high-voltage output circuit is included by a scan driving IC and a data driving IC as a driving IC of a plasma display panel and by a scan driving IC and a data driving IC as a driving IC of a flat display.
